(19) United States
(12) Patent Application Publication
(10) Pub. No.: US 2026/0164924 A1
(43) Pub. Date: Jun. 11, 2026

(54) LIGHT EMITTING DEVICE AND LIGHT EMITTING DISPLAY DEVICE INCLUDING THE SAME

(71) Applicant: LG Display Co., Ltd., Seoul (KR)

(72) Inventors: Kwang Jong KIM, Paju-si (KR); Do Yeong SHIN, Paju-si (KR); Su Min GWON, Paju-si (KR)

(73) Assignee: LG Display Co., Ltd., Seoul (KR)

(21) Appl. No.: 19/332,663

(22) Filed: Sep. 18, 2025

(30) Foreign Application Priority Data
Dec. 11, 2024 (KR) 10-2024-0183950

(51) Int. Cl. H10K 50/13; H10K 101/00; H10K 101/40

(52) U.S. Cl. CPC H10K 50/13; H10K 2101/40; H10K 2101/90

(57) ABSTRACT

A light emitting device and a display device including the same are discussed. The light emitting device can include a first electrode and a second electrode facing each other, and a first common layer, a first light emitting layer, and a second common layer disposed between the first electrode and the second electrode. The first light emitting layer can include a first layer, a second layer, and a third layer sequentially disposed between the first common layer and the second common layer, each containing a dopant. The first layer can include a first host, the second layer can include a second host having a lower triplet energy level than the first host, and the third layer can include the dopant singly.

### CROSS-REFERENCE TO RELATED APPLICATIONS

This application claims priority to Korean Patent Application No. 10-2024-0183950, filed in the Republic of Korea on Dec. 11, 2024, which is hereby incorporated by reference as if fully set forth herein.

### BACKGROUND OF THE INVENTION

### Field of the Invention

The present disclosure relates to a display device. More specifically, the present disclosure relates to a light emitting device and a light emitting display device including the same, which are imparted with improved efficiency and lifespan by changing a configuration of a light emitting layer.

### Discussion of the Related Art

With the advent of the information society, displays for visually expressing electrical information signals have rapidly developed. In response to this, a variety of display devices with excellent performance such as slimness, low weight, and low power consumption are being developed.

Among such display devices, a light emitting display device that does not require a separate light source to realize compactness and clear color and has a light emitting device in a display panel has been considered to have a competitive application.

The light emitting device can include an anode and a cathode facing each other as electrodes, a light emitting layer between the anode and the cathode, and a common layer for transferring holes and electrons to the light emitting layer.

The light emitting device can include various functional layers for various functions, for example, in the common layer. The functional layers include a hole transport layer for transferring holes to the light emitting layer and the electron transport layer for transferring electrons to the light emitting layer.

The light emitting device can further include color light emitting layers to express various colors. The efficiency and life characteristics of the color light emitting layers are different and the development of different device structures for each color light emitting layer is needed.

In addition, research on the application of light emitting devices including color light emitting layers with shorter lifespan is intensified to represent uniform color of the display devices.

### SUMMARY OF THE INVENTION

Accordingly, the present disclosure is directed to a light emitting display and a light emitting display device including the same that substantially obviate one or more problems due to limitations and disadvantages of the related art.

It is one aspect of the present disclosure to provide a light emitting device and a light emitting display device that include a plurality of light emitting layers with improved efficiency and reduced driving voltage.

It is another aspect of the present disclosure to provide a light emitting device and a light emitting display device with improved efficiency and lifespan.

It is another aspect of the present disclosure to provide a light emitting device and a light emitting display device that provide process optimization by reducing the number of chambers in the process of manufacturing light emitting devices.

It is another aspect of the present disclosure to provide a light emitting display device including a blue light emitting device with improved efficiency and lifespan.

Additional advantages, objects, and features of the invention will be set forth in part in the description which follows and in part will become apparent to those having ordinary skill in the art upon examination of the following or can be learned from practice of the invention. The objectives and other advantages of the invention can be realized and attained by the structure particularly pointed out in the written description and claims hereof as well as the appended drawings.

The light emitting devices and light emitting display devices including the same of the embodiments of the present disclosure include a first layer and a second layer including different hosts, and a third layer of a single dopant as the uppermost layer, so that multiple light emitting layers can be formed in a single chamber without additional manufacturing equipment, and also both the efficiency and lifespan of the light emitting devices can be improved.

To achieve these objects and other advantages and in accordance with the purpose of the disclosure, as embodied and broadly described herein, a light emitting device includes a first electrode and a second electrode facing each other, and a first common layer, a first light emitting layer, and a second common layer sequentially disposed between the first electrode and the second electrode, wherein the first light emitting layer includes a first layer, a second layer, and a third layer sequentially disposed between the first common layer and the second common layer, each containing a dopant, and the first layer includes a first host, the second layer includes a second host having a lower triplet energy level than the first host, and the third layer includes the dopant singly.

In accordance with another aspect of the present disclosure, a light emitting display device includes a substrate including a plurality of subpixels, a pixel circuit provided in each of the plurality of subpixels, and the light emitting device connected to a thin film transistor of the pixel circuit.

In accordance with another aspect of the present disclosure, a light emitting display device includes a light emitting display device including a substrate including a blue subpixel, a green subpixel, and a red subpixel, a pixel circuit provided in each of the blue subpixel, the green subpixel, and the red subpixel, a first electrode connected to a thin film transistor of the pixel circuit in each of the blue subpixel, the green subpixel, and the red subpixel, a second electrode facing the first electrode, and a first common layer and a second common layer disposed between the first electrode and the second electrode, wherein the blue subpixel comprises a first blue light emitting layer comprising a blue dopant between the first common layer and the second common layer, the green subpixel comprises a first green light emitting layer comprising a green dopant between the first common layer and the second common layer, the red subpixel comprises a first red light emitting layer comprising a red dopant between the first common layer and the second common layer, the first blue light emitting layer comprises the blue dopant and comprises a first layer, a second layer, and a third layer sequentially disposed, and the first layer comprises a first host, and the second layer comprises a second host having a lower triplet energy level than the first host.

It is to be understood that both the foregoing general description and the following detailed description of the present disclosure are examples and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a cross-sectional view illustrating a light emitting device according to an embodiment of the present disclosure;

FIG. 2 is an energy band diagram showing the structure of the light emitting layer of FIG. 1;

FIGS. 3A to 3E are cross-sectional views illustrating a method of manufacturing the light emitting layer of FIG. 1 according to an embodiment of the present disclosure;

FIG. 4 is energy band diagrams of the light emitting layers of Experimental Examples 1, 2, and 3;

FIG. 5 is a graph showing the 95 lifespan of the light emitting devices to which Experimental Examples 1 and 2 are applied;

FIG. 6 is a graph showing the luminance depending on CIEy of the light emitting devices to which Experimental Examples 1 and 2 are applied;

FIG. 7 is a graph showing the 98 lifespan of the light emitting devices according to Experimental examples 1, 2 and 3;

FIG. 8 is an energy band diagram of the structure of Experimental Example 4 EX4 including a single dopant film between the first layer EMA1 and the second layer EMA2;

FIG. 9 is a cross-sectional view illustrating a light emitting device according to another embodiment of the present disclosure;

FIG. 10 is a cross-sectional view illustrating a light emitting device according to another embodiment of the present disclosure;

FIG. 11 is a cross-sectional view illustrating a light emitting display device including the light emitting device according to an embodiment of the present disclosure; and

FIG. 12 is a cross-sectional view illustrating a light emitting display device according to another embodiment of the present disclosure.

### DETAILED DESCRIPTION OF THE EMBODIMENTS

Advantages and features of the present disclosure, and a method of achieving the advantages and features will become apparent with reference to the example embodiments described herein in detail together with the accompanying drawings. The present disclosure should not be construed as limited to the example embodiments as disclosed below, and can be embodied in various different forms. Thus, these example embodiments are set forth only to make the present disclosure sufficiently complete, and to assist those skilled in the art to fully understand the scope of the present disclosure. The protected scope of the present disclosure is defined by the claims and their equivalents.

In the following description of the present disclosure, where the detailed description of the relevant known steps, elements, functions, technologies, and configurations can unnecessarily obscure an important point of the present disclosure, a detailed description of such steps, elements, functions, technologies, and configurations may be omitted or may be provided briefly. In addition, the names of elements used in the following description are selected in consideration of clarity of description of the specification, and can differ from the names of elements of actual products. Furthermore, in the following detailed description of the present disclosure, numerous specific details are set forth in order to provide a sufficiently thorough understanding of the present disclosure. However, it will be understood that the present disclosure can be practiced without these specific details. In other instances, known methods, procedures, components, and circuits have not been described in detail so as not to unnecessarily obscure aspects of the present disclosure.

The shapes, sizes, ratios, angles, numbers, and the like, which are illustrated in the drawings to describe various example embodiments of the present disclosure are merely given by way of example. The disclosure is not limited to the illustrations in the drawings.

In the present specification, where terms such as “including,” “having,” “comprising,” and the like are used, one or more components can be added, unless the term, such as “only,” is used. As used herein, the term “and/or” includes a single associated listed item and any and all of the combinations of two or more of the associated listed items.

An expression such as “at least one of” when preceding a list of elements can modify the entire list of elements and may not modify the individual elements of the list. The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, and the third element.

The terminology used herein is to describe particular aspects and is not intended to limit the present disclosure. As used herein, the terms “a” and “an” used to describe an element in the singular form is intended to include a plurality of elements. An element described in the singular form is intended to include a plurality of elements, and vice versa, unless the context clearly indicates otherwise.

In construing a component or numerical value, the component or the numerical value is to be construed as including an error or tolerance range even where no explicit description of such an error or tolerance range is provided.

In describing the various example embodiments of the present disclosure, where the positional relationship between two elements is described using terms, such as “on”, “above”, “under” and “next to”, at least one intervening element can be present between the two elements, unless “immediate(ly)” or “direct(ly)” or “close(ly) is used. It will be understood that when an element or layer is referred to as being “connected to”, or “coupled to” another element or layer, it can be directly connected to or coupled to the other element or layer, or one or more intervening elements or layers can be present.

In describing the various example embodiments of the present disclosure, when terms such as “after,” “subsequently,” “next,” and “before,” are used to describe the temporal relationship between two events, another event can occur therebetween, unless a more limiting term, such as “just,” “immediate(ly),” or “directly” is used.

In describing the various example embodiments of the present disclosure, terms such as “first” and “second” can be used to describe a variety of components. These terms aim to distinguish the same or similar components from one another and do not limit the components. Accordingly, throughout the specification, a “first” component can be the same as a “second” component within the technical concept of the present disclosure, unless specifically mentioned otherwise. Further, the term “can” fully encompasses all the meanings and coverages of the term “may” and vice versa.

Features of various embodiments of the present disclosure can be partially or overall coupled to or combined with each other, and can be variously inter-operated with each other and driven technically as those skilled in the art can sufficiently understand. The embodiments of the present disclosure can be carried out independently from each other, or can be carried out together in a co-dependent relationship.

As used herein, the term “doped” layer refers to a layer including a first material and a second material (for example, n-type and p-type materials, or organic and inorganic substances) having physical properties different from the first material. Apart from the differences in properties, the first and second materials can also differ in terms of their amounts in the doped layer. For example, the host material can be a major component while the dopant material can be a minor component. The first material accounts for most of the weight of the doped layer. The second material can be added in an amount less than 30% by weight, based on a total weight of the first material in the doped layer. A “doped” layer can be a layer that is used to distinguish a host material from a dopant material of a certain layer, in consideration of the weight ratio. For example, if all of the materials constituting a certain layer are organic materials, at least one of the materials constituting the layer is n-type and the other is p-type, when the n-type material is present in an amount of less than 30 wt %, or when the p-type material is present in an amount of less than 30 wt %, the layer is considered to be a “doped” layer.

Further, the term “undoped” refers to layers that are not “doped”. For example, a layer can be an “undoped” layer when the layer contains a single material or a mixture including materials having the same properties as each other. For example, if at least one of the materials constituting a certain layer is p-type and none of the materials constituting the layer are n-type, the layer is considered to be an “undoped” layer. For example, if at least one of the materials constituting a layer is an organic material and none of the materials constituting the layer are inorganic materials, the layer is considered to be an “undoped” layer.

In this present disclosure, an electroluminescence (EL) spectrum can be calculated by multiplying (a) a photoluminescence (PL) spectrum, which applies the inherent characteristics of an emissive material such as a dopant material or a host material included in an organic emission layer, by (b) an outcoupling or emittance spectrum curve, which is determined by the structure and optical characteristics of an organic light-emitting element including the thicknesses of organic layers such as, for example, an electron transport layer.

Hereinafter, example embodiments of the present disclosure will be described in detail with reference to the accompanying drawings. All the components of each light emitting device and each display device/apparatus according to all embodiments of the present disclosure are operatively coupled and configured. In adding reference numerals to elements of each of the drawings, although the same elements are illustrated in other drawings, like reference numerals can refer to like elements.

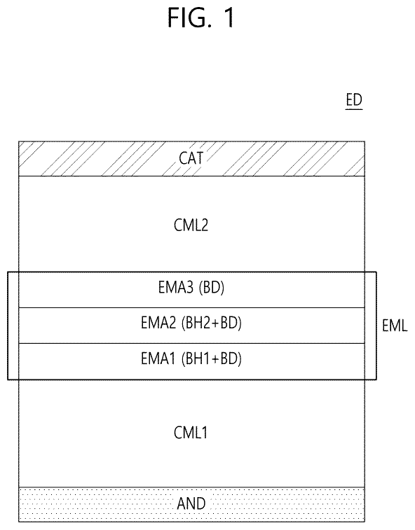

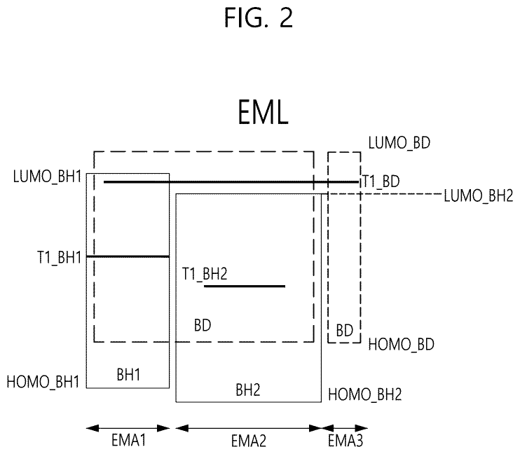

FIG. 1 is a cross-sectional view illustrating a light emitting device according to one embodiment of the present disclosure. FIG. 2 is an energy band diagram showing the structure of the light emitting layer of FIG. 1.

As shown in FIG. 1, a light emitting device ED according to one embodiment of the present disclosure includes a first electrode AND and a second electrode CAT facing each other, and a first common layer CML1, a light emitting layer EML, and a second common layer CML2 that are sequentially disposed between the first electrode AND and the second electrode CAT.

At least one of the first electrode AND and the second electrode CAT is transparent or semi-transparent, and light generated in the light emitting device ED is transmitted through the transparent or semi-transparent electrode. For example, when the first electrode AND includes a reflective electrode and the second electrode CAT includes a semi-transparent or transparent electrode, the light emitting device ED can be a top-emission type.

As another example, when the first electrode AND includes a transparent electrode and the second electrode CAT includes a reflective electrode, the light emitting device ED can be a bottom-emission type. As another example, the first electrode AND and the second electrode CAT can be transparent or semi-transparent electrodes, so that the light emitting device ED can emit light in both directions.

The first electrode AND can function as an anode and the second electrode CAT can function as a cathode. The first electrode AND can be connected to the thin film transistor of the pixel circuit provided in each subpixel on the substrate. The second electrode CAT can be provided in common to each subpixel and can receive a common voltage signal at least from the outside.

The first common layer CML1 can include, for example, at least one of a hole injection layer, a hole transport layer, or an electron blocking layer. Each of the hole injection layer, the hole transport layer, and the electron blocking layer can be selected from a material that includes a hole transport material or a material that does not inhibit the flow of holes. The configuration of the first common layer CML1 in contact with one side of the light emitting layer EML (the lower surface of the light emitting layer EML in FIG. 1) can be a hole transport layer or an electron blocking layer.

The second common layer CML2 can include, for example, at least one of a hole blocking layer, an electron transport layer, or an electron injection layer. The second common layer CML2 that contacts the other side of the light emitting layer EML (the upper surface of the light emitting layer EML of FIG. 1) can be a hole blocking layer or an electron transport layer. The hole blocking layer and the electron transport layer can each include an electron transport material or can be selected from a material that does not inhibit the flow of electrons.

The light emitting device ED of the embodiments of the present disclosure includes at least one light emitting layer EML including a plurality of layers and the uppermost layer of the light emitting layer EML including a plurality of layers includes a third layer EMA3 containing a single dopant BD.

For example, as shown in FIGS. 1 and 2, the light emitting layer EML includes a first layer EMA1, a second layer EMA2, and a third layer EMA3 that are sequentially disposed between the first common layer CML1 and the second common layer CML2. The first layer EMA1, the second layer EMA2, and the third layer EMA3 each include a dopant.

The dopant BD commonly included in each layer EMA1, EMA2, and EMA3 of the light emitting layer EML can be a fluorescent dopant and can be a dopant capable of delayed fluorescence. For example, the same dopant BD can be included in each layer EMA1, EMA2, and EMA3.

The dopant BD in the light emitting layer EML (e.g., EMA1, EMA2, and/or EMA3) is a fluorescent dopant having an emission peak at a wavelength of 430 nm to 495 nm. For example, the dopant BD can include a boron-based dopant, as shown in the following Formulas 1 to 9. However, this is merely provided as an example and the dopant in the embodiments of the present disclosure is not limited to the following materials. Any fluorescent dopant can be used as long as it is capable of fluorescence emission and delayed fluorescence emission, has an emission peak at a wavelength of visible light of 495 nm or less, and has a high triplet energy level.

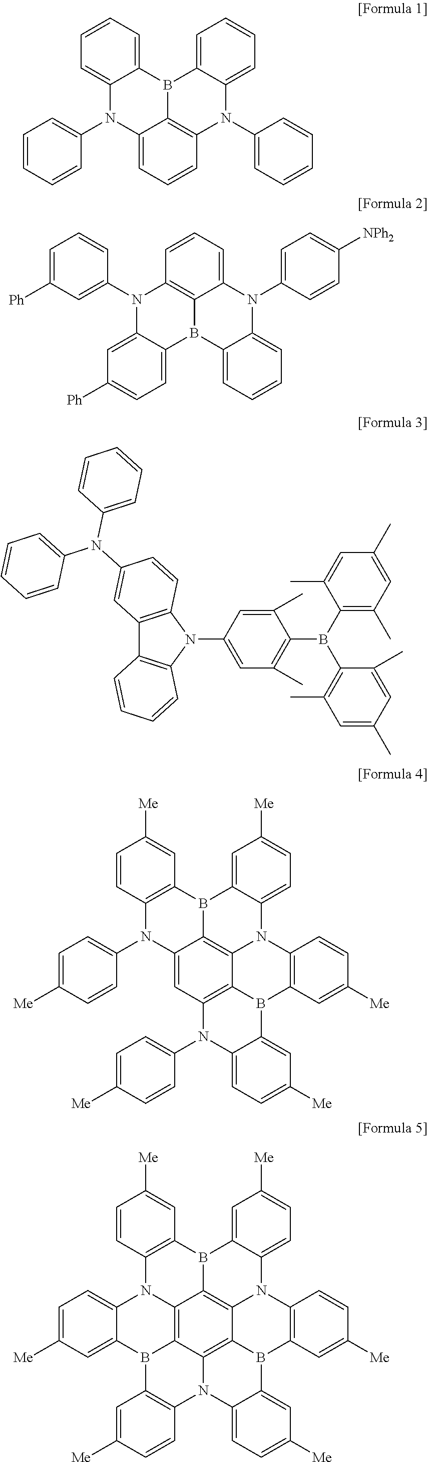

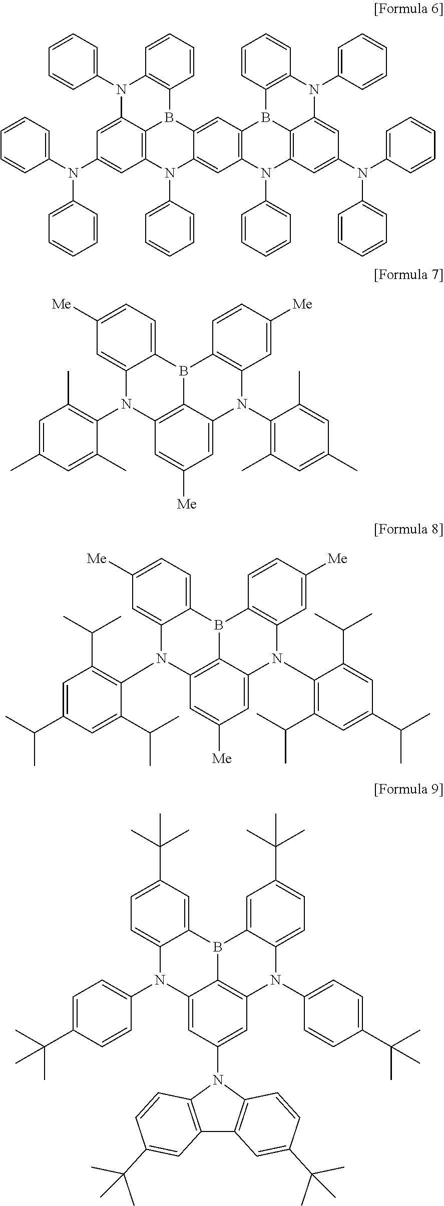

In addition, the triplet energy level of the dopant can be adjusted to be high by changing the substituent in at least a part of any one of the compounds of Formulas 1 to 9 described above in the light emitting device according to the embodiment of the present disclosure.

Here, each of the first layer EMA1 and the second layer EML2 includes, in addition to the dopant BD, a first host BH1 and a second host BH2 that assist the excitation of the dopant BD, and the third layer EMA3 includes only the dopant BD. The first layer EMA1 and the second layer EMA2 have different host components. The hosts BH1 and BH2 are present in main contents in the first and second layers, EMA1 and EMA2, respectively. The first host BH1 is contained in an amount of 50 wt % or more in the first layer EMA1, and the second host BH2 is contained in an amount of 50 wt % or more in the second layer EMA2. More preferably, the first and second hosts BH1 and BH2 can be present in an amount of 70 wt % or more in the first and second layers EMA1 and EMA2, respectively.

More preferably, at least one of the first and second layers EMA1 and EMA2 can contain the first and second hosts BH1 and BH2 in an amount of 90 wt % or more. In this case, the dopant BD can be present in an amount of 10 wt % or less in the first and second layers EMA1 and EMA2. For example, the first layer EMA1 can contain 90 wt % or more of the first host BH1, the second layer EMA2 can contain 70 wt % of the second host BH2 and can further contain 20 wt % or more of another host that has a triplet energy level lower than that of the first host BH1 and is different from the second host BH2.

The first host BH1, the second host BH2, and the dopant BD, which are components contained in the light emitting layer EML, have the following relationship in terms of triplet energy level T1:

$$T1\_BD > T1\_BH1 > T1\_BH2$$

For example, among the components contained in the light emitting layer EML, the triplet energy level T1_BD of the dopant BD is the highest and the triplet energy level T1_BH1 of the first host BH1 contained in the first layer EMA1 is higher than the triplet energy level T1_BH2 of the second host BH2 contained in the second layer EMA2.

In the first layer EMA1, electrons and holes recombine and then light is immediately emitted, and in the second layer EMA2, energy is transferred from the triplet energy level T1_BH1 of the first host BH1 of the first layer EMA1 to the triplet energy level T1_BH2 of the second host BH2, and triplet excitons collide, resulting in delayed light emission based on triplet-triplet fusion (TTF) mechanism generating singlet excitons. For example, regions of the first and second layers EMA1 and EM2 are distinguished by the host components BH1 and BH2 each having a difference in triplet energy level T1_BH1, and T1_BH2, and the first region EMA1 optimally performs immediate light emission and the second region EMA2 optimally performs delayed light emission.

In the first layer EMA1, electrons and holes recombine, generating singlet excitons and triplet excitons. Theoretically, singlet excitons and triplet excitons are generated in a ratio of 1:3. The singlet excitons generated in the first layer EMA1 fall from the singlet energy level S1_BD of the dopant BD to the ground state and fluorescence occurs immediately. For more effective fluorescence in the first layer EMA1, the dopant BD can have a triplet energy level higher than the triplet energy level T1_BH1 of the first host BH1 (T1_BD>T1_BH1), but can have a singlet energy level lower than the singlet energy level S1_BH1 of the first host BH1 (S1_BD<S1_BH1).

The singlet excitons generated within the first layer EMA1 are readily transferred to the low singlet energy level S1_BD of the dopant BD due to the low singlet energy level of the dopant BD, thereby contributing to the fluorescence of the dopant BD in the first layer EMA1.

In addition, the triplet excitons generated within the first layer EMA1 are not moved to the dopant BD with a high triplet energy level, but to the first host BH1 having a lower triplet energy level than the dopant BD. In addition, due to the relationship in the triplet energy level difference (T1_BH1>T1>BH2) between the first host BH1 and the second host BH2, molecules of triplet excitons can move from the first host BH1 to the second host BH2 having a lower triplet energy level and the triplet excitons moved to the second layer EMA2 generate singlet excitons based on the TTF mechanism to perform delayed fluorescence within the second layer EMA2. In addition, the second layer EMA2 can generate both singlet excitons and triplet excitons within the second layer EMA2 by supplying holes through the first common layer CML1 generated within the second layer EMA2 and supplying electrons through the second common layer CML2, and the fluorescence by the singlet excitons generated within the second layer EMA2, the triplet excitons directly generated by the second host BH2 collide with the triplet excitons transferred from the first host BH1 due to the triplet energy level difference, generating singlets, and the light emission efficiency based on the TTF mechanism in the second layer EMA2 is improved by the delayed fluorescence generated by the excitation effect thereof.

When the excitons within the light emitting layer are not used for light emission, they can interact with the surrounding polarons and be quenched. Quenching can be a major factor lowering the efficiency of the light emitting layer. In addition, when excitons not used for light emission accumulate at the interface that contacts the first common layer CML1 among the light emitting layers, it can have a fatal effect on the lifespan of the light emitting device.

The light emitting device according to an embodiment of the present disclosure is capable of facilitating energy transfer of triplet excitons between the first and second hosts BH1 and BH2 by adjusting the triplet energy level T1_BH1 of the first host BH1 provided in the first layer EMA1 to be higher than the triplet energy level T1_BH2 of the second host BH2 provided in the second layer EMA2, and is capable of increasing the exciton recycling rate, maximizing the light emitting efficiency in the light emitting layer EML, maximizing the TTF efficiency in the second layer EMA2 and further improving the lifespan by transferring the triplet excitons in the region of the first layer EMLA in contact with the first common layer CML1 through energy transfer to the second layer EMA2, without allowing the triplet excitons to accumulate. On the other hand, when a single light emitting layer is applied, the interface between the light emitting layer and the common layer, especially the interface where the light emitting layer and the hole transport layer come into contact, is markedly affected by the decrease in the lifespan due to the accumulation of excitons.

Accordingly, the light emitting device according to the embodiment of the present disclosure generates light emission of the first layer EMA1 and the second layer EMA2 within the light emitting layer EML, and in particular, can be used for light emission without the quenching phenomenon of triplet excitons, thereby maximizing light emission efficiency.

The first host BH1 can be, for example, a compound including a pyrene derivative.

The second host BH2 can be, for example, a compound including an anthracene derivative.

The above-described examples are examples of materials found from the following experiments. Other materials for the first and second hosts BH1 and BH2 and the dopant BD can be used as long as the triplet energy level difference relationship between the dopant BD, the first host BH1, and the second host BH2 is satisfied.

Unlike as shown in FIGS. 1 and 2, when the light emitting layer includes a plurality of light emitting layers and the first layer adjacent to the first common layer CML1 includes a host having a low triplet energy level, triplet excitons can move to the first layer and concentrate at the interface contacting the first common layer, resulting in an increase in the excitons that are not used for light emission and are quenched, which can have a negative effect on both light emission efficiency and lifespan.

Another feature of the light emitting device according to the embodiment of the present disclosure is characterized in that it includes a third layer EMA3 in addition to the first layer EMA1 and the second layer EMA2 having one of the first and second hosts BH1 and BH2 that are different from each other. The third layer EMA3 contains a single dopant BD.

The light emitting device according to the embodiment of the present disclosure is a structure formed in a single chamber. For example, when the light emitting layer includes a plurality of layers, although the materials for forming the respective layers are formed separately, the number of times of loading/unloading the material in the chamber on the substrate can be reduced by using a single chamber, and yield reduction due to alignment errors that can occur during loading/unloading can be prevented and the process can be optimized. The detailed method of manufacturing the light emitting layer will be described later.

In addition, the light emitting device according to the embodiment of the present disclosure can have a thickness difference in the light emitting layer EML as shown in FIG. 2. The second layer EMA2 is thicker than the first layer EMA1 and the third layer EMA3 can be designed to be the thinnest.

The intensity of emitted light in the light emitting layer EML can vary depending on the recombination rate of holes and electrons. For example, the interface of the first and second layers EML1 and EML2 with high recombination rates can have the strongest luminescence intensity and the interface between the first layer EMA1 with low recombination rates and the first common layer CML1 or the interface between the second layer EMA2 and the third layer EMA3 can be the smallest. The third layer EMA3 is formed by selectively depositing a plurality of materials in a single chamber, is very thin, and may not be directly used for luminescence.

The second common layer CML2 in contact with the third layer EMA3 can include an electron transport material. The third layer EMA3 is a very thin layer. Although the LUMO (Lowest Unoccupied Molecular Orbital) energy level of the third layer EMA3 is higher than the LUMO energy level of the second common layer CML2 through the adjacent second common layer CML2, electrons move from the second common layer CML2 to the light emitting layer EML without an energy barrier by the third layer EMA3.

The third layer EMA3 can have a thickness of 0.1 Å to 5 Å. Since the third layer EMA3 is very thin, it does not affect the driving voltage when the light emitting device ED is driven.

The thickness of the second layer EMA2 can be at least twice the thickness of the first layer EMA1 and the thickness of the third layer EMA3 can be 1/200 to 1/10 times the thickness of the first layer EMA1.

Meanwhile, the light emitting device according to the embodiment of the present disclosure described above includes a light emitting layer EML that emits light with a wavelength of 430 nm to 495 nm, approximately blue light.

Since users have low visibility to blue light and blue light emitting devices have a short lifespan, it is considered a major task to improve efficiency and lifespan of blue light emitting devices, compared to other color light emitting devices. The light emitting device according to the embodiment of the present disclosure forms a plurality of blue light emitting layers and uses different internal materials to separate the layers, thereby improving both light emitting efficiency and lifespan.

However, the embodiment of the present disclosure is not limited to a light emitting device that emits blue light. Although a light emitting device includes a light emitting dopant that emits light with other color, the light emitting layer is divided into a first layer, a second layer, and a third layer, the first layer includes a first host, the second layer includes a second host having a lower triplet energy level than the first host, and the third layer includes the dopant alone, so that the effect of improving both the efficiency and lifespan of the light emitting device according to the embodiment described above can be obtained. In this case, the dopant can be a fluorescent dopant capable of fluorescence and delayed fluorescence for efficiency improvement based on the TTF mechanism.

The light emitting device according to the embodiment of the present disclosure includes a third layer EMA3 including a dopant alone in addition to the first layer EMA1 and the second layer EMA2 including a host. In addition, the following method of manufacturing the light emitting layer is used to form the first layer EMA1, the second layer EMA2, and the third layer EMA3 in a single chamber.

Hereinafter, a method of manufacturing the light emitting device according to one or more embodiments of the present disclosure will be described.

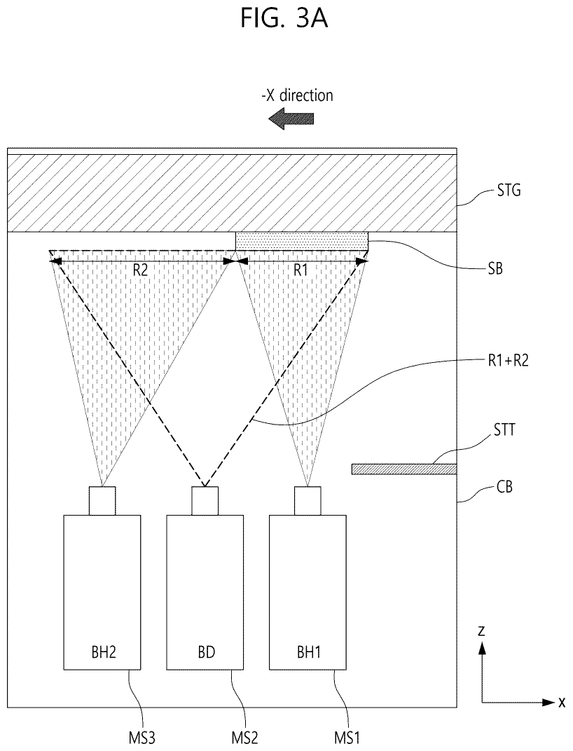

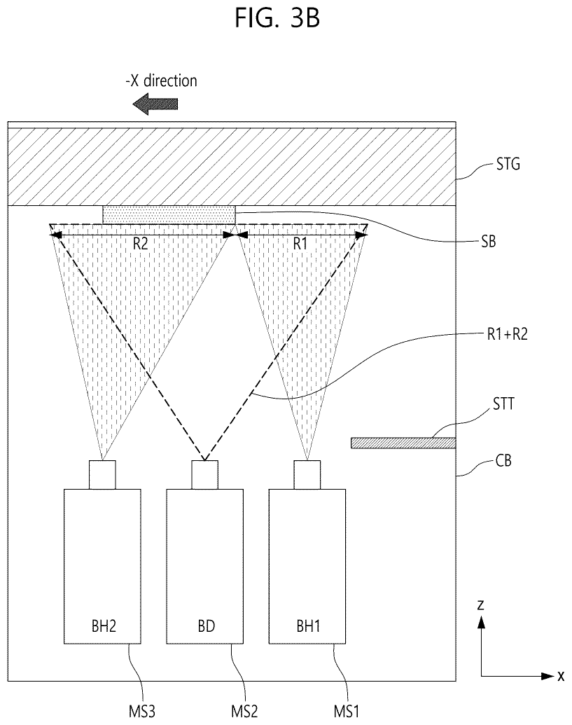

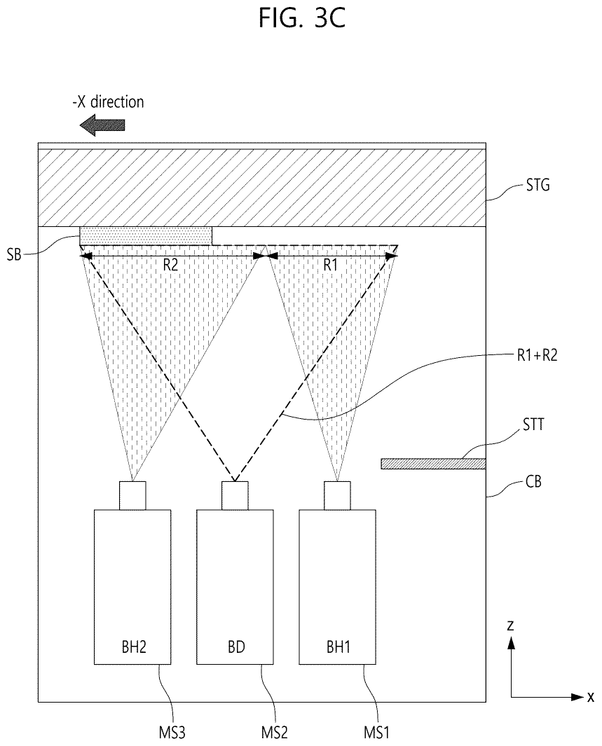

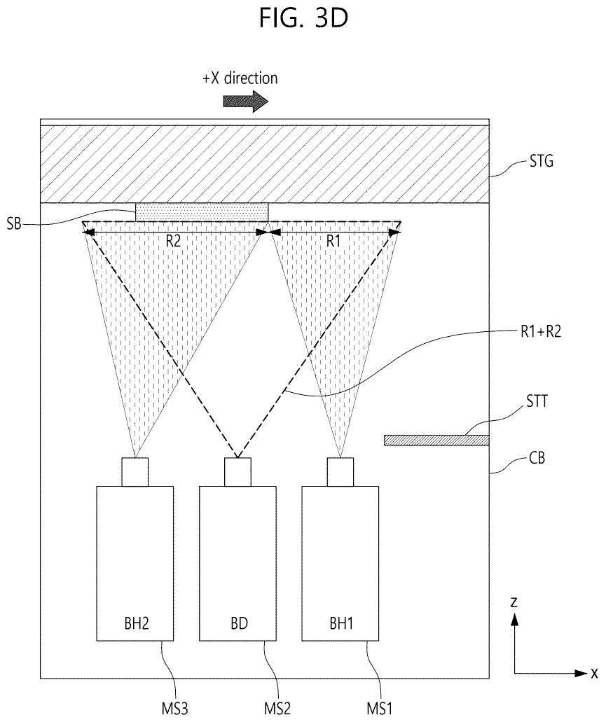

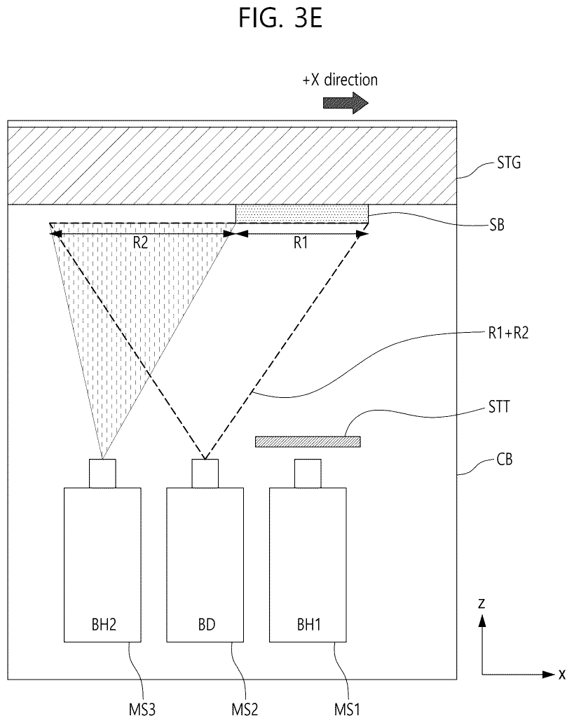

FIGS. 3A to 3E are cross-sectional views illustrating a method of manufacturing the light emitting layer of FIG. 1 according to one or more embodiments of the present disclosure.

As shown in FIG. 3A, a first supply source MS1 to supply a first host BH1, a second supply source MS2 to supply a dopant BD, and a third supply source MS3 to supply a second host BH2 are provided side by side in a chamber CB.

A stage STG is provided on the upper side of the chamber CB facing the first, second, and third supply sources MS1, MS2 and MS3. A substrate SB can be loaded from the outside of the chamber CB on one surface of the stage STG facing the first to third supply sources MS1, MS2 and MS3, and the substrate SB can be mounted.

A first deposition region R1 in which a first host BH1 is supplied from a first supply source MS1 and a second deposition region R2 in which a second host BH2 is supplied from a third supply source MS3 are separated from each other. The left end of the first deposition region R1 and the right end of the second deposition region R2 can be in contact with each other. The deposition region in which a dopant BD is supplied from the second supply source MS2 can be a region where the first deposition region R1 is combined with the second deposition region R2. The deposition region can be adjusted by adjusting the deposition angle of the material from each supply source. Here, the amount of the first host BH1 or the second host BH2 supplied to the same region is set to be greater than the amount of the dopant BD supplied thereto. Each supply amount can be controlled by changing the deposition speeds of the first to third supply sources MS1, MS2 and MS3. The deposition rate of the second source MS2 can be slower than that of the first and third sources MS1 and MS3. Therefore, when the first and second layers EMA1 and EMA2 are formed, the first host BH1 and the second host BH2 are the main components in each layer.

The stage STG can move the substrate in the ±X-axis direction.

The first to third supply sources MS1, MS2 and MS3 are spaced apart from the stage STG in the Y-axis direction.

The substrate SB loaded into the chamber CB is mounted on the stage STG. A region of the substrate SB on which deposition is performed is formed up to the first common layer CML1 on the first electrode AND based on the light emitting device ED of FIG. 1.

When the substrate SB moves, the surface on which the deposition material is formed is disposed so that the first common layer CML1 on the substrate SB faces the first to third supply sources MS1, MS2 and MS3 so that it is on the upper side of the first common layer CML1.

As shown in FIG. 3A, the substrate SB is first loaded onto the stage STG in the chamber CB and then is moved in the −X-axis direction such that the substrate SB corresponds to the first deposition region R1. A first layer EMA1 including a first host BH1 and a dopant BD is formed in the first deposition region R1 of the substrate SB.

Then, as shown in FIGS. 3B and 3C, the stage STG is moved in the −X-axis direction so that the substrate SB corresponds to the second deposition region R1. The second host BH2 and the dopant BD are supplied together in the second deposition region R2 of the substrate SB. This determines the initial thickness of the second layer EMA2.

Then, as shown in FIG. 3D, after the substrate SB is disposed at one end of the second deposition region R2, the stage STG is moved in the opposite direction, for example, the +X-axis direction, and the second host BH2 and the dopant BD are supplied together in the second deposition region R2 of the substrate SB. The second layer EMA2 is formed through the processes of FIGS. 3B to 3D.

Since the second layer EMA2 is formed by reciprocating the substrate in the −X-axis direction and the +X-axis direction in the second deposition region R2 that is longer than the first deposition region R1, the thickness of the first layer EMA1 formed by moving the substrate in the −X-axis direction in the first deposition region R1 can be at least twice that of the first layer EMA1.

After the formation of the second layer EMA2 is completed, a shutter STT is disposed above the first supply source MS1 to block the supply of the first host BH1 from the first supply source MS1 to the first deposition region R1. Here, the supply region of the second host BH2 is outside the first deposition region R1. Therefore, after the shutter STT is loaded on the upper side of the first supply source MS1, and the substrate SB is moved in the +X-axis direction to the first deposition region R1, only the dopant BD is supplied to the substrate SB and thus a third layer EMA3 of a single dopant BD is formed.

As such, the light emitting layers of the light emitting device according to the embodiment of the present disclosure are formed by adjusting the deposition region and using the shutter in the same chamber. Therefore, when the light emitting layers are formed using chambers, there is an advantage of solving the problems of reduced yield and additional process equipment that occur whenever each chamber is disposed.

In addition, the third layer EMA3 is located at the top layer of the light emitting layer EML which is the farthest from the interface of the first and second layers EMA1 and EMA2 where the main light emission occurs, and the deposition speed is slowed down to make the thickness very thin, thereby preventing the deterioration problem due to the provision of the third layer EMA3 in the light emitting layer EML and maintaining the effect of improved efficiency and increased lifespan due to the partitioning of the first and second layers EMA1 and EMA2.

The light emitting device according to the embodiment of the present disclosure includes the third layer EMA3 at the top layer of the light emitting layer EML so that the third layer EMA3 is spaced apart from the interface of the first and second layers EMA1 and EMA2 where excitons are dominantly formed, thereby preventing carrier traps of holes or electrons from occurring in the third layer EMA3, and simultaneously securing the performance of the light emitting layer EML and improving lifespan.

Hereinafter, the effect of the light emitting device of the present disclosure will be described through experiments.

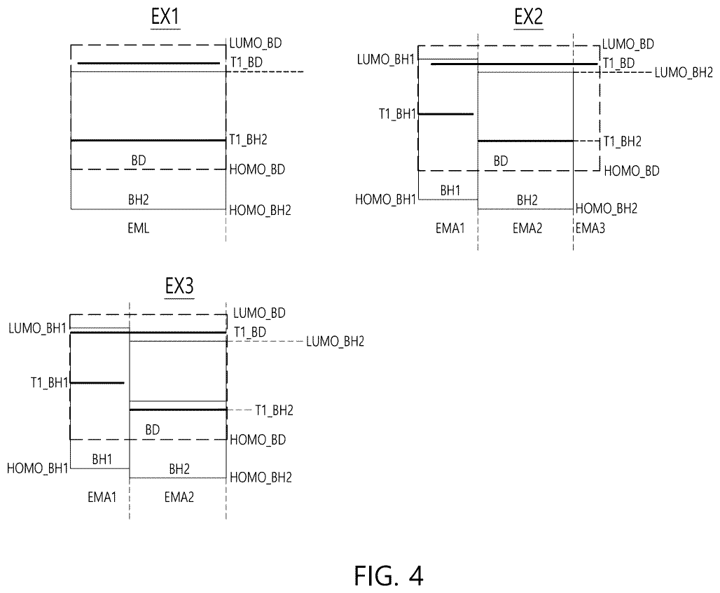

FIG. 4 is energy band diagrams of the light emitting layers of Experimental Examples 1, 2, and 3.

As shown in FIG. 4, Experimental Example 1 EX1 has the same configuration as in the light emitting device of FIG. 1, except that the light emitting layer is configured as a single layer, and the single light emitting layer includes a second host BH2 and a blue light emitting dopant BD. Here, the total thickness of the light emitting layer EML of Experimental Example 1 EX1 is 180 Å.

Experimental example 2 EX2 has the same configuration as in the light emitting device of FIG. 1. Accordingly, the first layer EMA1 includes the first host BH1 and the dopant BD, the second layer EMA2 includes the second host BH2 and the dopant BD, and the third layer EMA3 includes the dopant BD alone. In the light emitting layer EML of Experimental Example 2 EX2, the first layer EMA1 was formed to a thickness of 50 Å, the second layer EMA2 was formed to a thickness of 130 Å, and the third layer EMA3 was formed to a thickness of 0.5 Å.

Experimental Example 3 EX3 has the same configuration as in the light emitting device of FIG. 1 except that it does not include the third layer EMA3. However, the structure of Experimental Example 3 EX3 cannot be implemented using scan deposition in a single chamber. The first and second hosts are sequentially deposited and the first layer EMA1 including the first and second hosts and the second layer EMA2 are formed in different chambers in order for the second layer including the second host to become the uppermost surface of the light emitting layer. In this case, additional manufacturing equipment can be required due to the use of multiple chambers for the formation of the light emitting layer and the yield of the light emitting display device can decrease due to alignment errors when the substrate is loaded into each chamber.

In Experimental Examples 1, 2 and 3 EX1, EX2, and EX3, the content of the dopant BD in the light emitting layer or the first and second layers was set to 1 wt %.

The triplet energy levels of the first host BH1, the second host BH2, and the dopant BD used in the experiments are shown in Table 1.

TABLE 1

| Item | BD | BH1 | BH2 |
|---|---|---|---|
| T1[eV] | 2.7 | 2.1 | 1.8 |

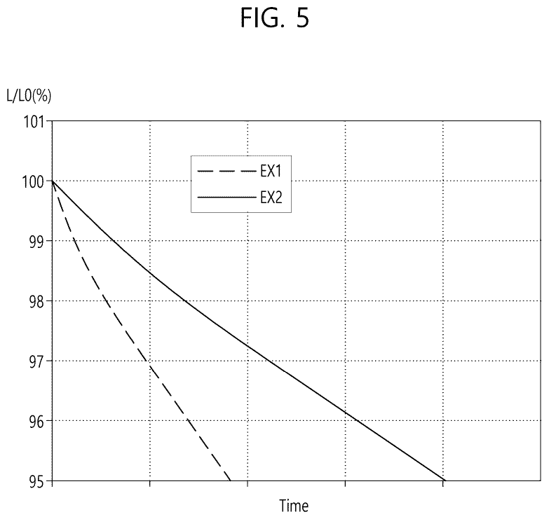

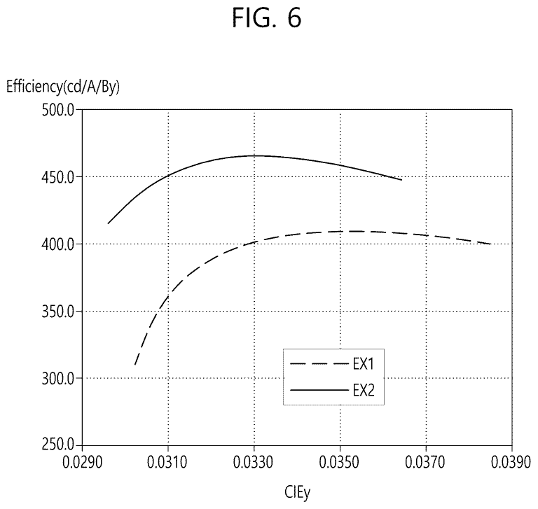

First, referring to FIGS. 5 and 6, the effects will be compared between Experimental Example 1 EX1 including a single light emitting layer containing a single host and Experimental Example 2 EX2 including the first and second layers EMA1 and EMA2 containing different hosts and a third layer EMA3 containing a single dopant as the uppermost layer.

FIG. 5 is a graph showing the 95 lifespan of the light emitting devices to which Experimental Examples 1 and 2 are applied. FIG. 6 is a graph showing the luminance depending on CIEy of the light emitting devices to which Experimental Examples 1 and 2 are applied.

The 95 lifespan means the lifespan until the luminance reaches 95% of the initial luminance.

As can be seen from FIG. 5, in Experimental Example 2 EX2 in which the first and second hosts BH1 and BH2 are separated to form the first and second layers EMA1 and EMA2 and the third layer EMA3 of the single composition of the dopant BD is formed on the second layer EMA2, it has the effect of increasing the lifespan by more than twice that of Experimental Example 1 EX1.

FIG. 6 shows the luminance of Experimental Examples 1 and 2 EX1 and EX2 at CIEy of 0.0290 to 0.0390, where the luminance of pure blue occurs. It can be seen that the luminous efficiency of Experimental Example 2 EX2 is improved compared to the luminous efficiency of Experimental Example 1 EX1 in the entire CIEy range of 0.0290 to 0.0390.

It can be seen from the experiment that both the lifespan and the pure color efficiency are improved in Experimental Example 2 EX2 of the light emitting layer configuration including the host divided into the first and second layers and the third layer of the dopant as the top layer, compared to Experimental Example 1 EX1 of the light emitting layer configuration including the host of a single material.

TABLE 2

| | | Driving | Blue | |
|---|---|---|---|---|
| | Structure of light | voltage | Index | Lifespan |
| Item | emitting layer | (V) | (%) | (%) |
| EX1 | (BH2 + BD) | Vr | 100 | 100 |
| EX2 | (BH1 + BD)/(BH2 + BD)/BD | Vr-0.140 | 109.3 | 363 |
| EX3 | (BH1 + BD)/(BH2 + BD) | Vr-0.150 | 112.6 | 363 |

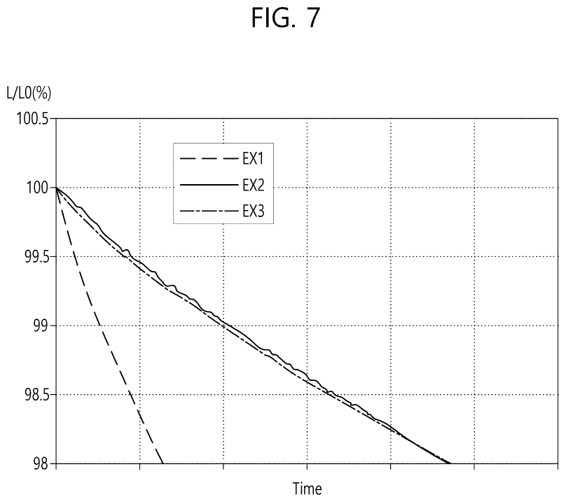

FIG. 7 is a graph showing the 98 lifespan of the light emitting devices according to Experimental Examples 1, 2 and 3.

Here, the blue index (%) refers to the value obtained by dividing the blue luminous efficiency of the light emitting layer by the blue CIEy. This can be evaluated as an indicator of pure blue.

The 98 lifespan of the light emitting device refers to the lifespan until the luminance reaches 98% of the initial luminance of the light emitting device.

As can be seen from Table 2 and FIG. 7, the driving voltage is significantly reduced and the blue index efficiency is improved in Experimental Example 2 EX2 and Experimental Example 3 EX3 compared to Experimental Example 1 EX1. In addition, it can be seen that the lifespan is improved by more than three times in Experimental Example 2 EX2 and Experimental Example 3 EX3, compared to Experimental Example 1 EX1.

Meanwhile, as can be seen from Table 2, Experimental Example 2 EX2 including the third layer EMA3 containing only the dopant exhibits the same lifespan as Experimental Example 3 EX3 including only the first and second layers, but exhibits slightly different efficiency therefrom. However, as described above, the light emitting layer having the structure of Experimental Example 3 EX3 is difficult to implement with a single chamber of the scan type. In the light emitting device according to the embodiment of the present disclosure, the light emitting layer is formed using the manufacturing method shown in FIGS. 3A to 3E, and can be implemented by selectively providing a shutter in a single chamber. The light emitting device according to the embodiment of the present disclosure can have additional effects of reducing yield deterioration or mask-induced defects and costs that occur when a plurality of chambers are provided by providing the light emitting layer having a multilayer structure in a single chamber.

In addition, as described above, the light emitting device according to Experimental Example 2 having a multilayered light emitting layer structure including the third layer that is implemented in one chamber can exhibit significantly improved effects in terms of driving voltage, blue index efficiency, and lifespan compared to the light emitting device according to Experimental Example 1 having a single light emitting layer.

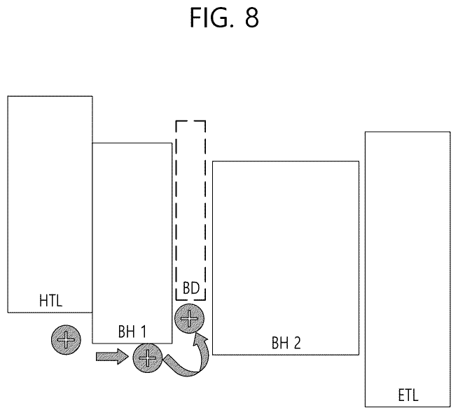

FIG. 8 is an energy band diagram of the structure of Experimental Example 4 EX4 including a single dopant film between the first layer EMA1 and the second layer EMA2.

As shown in FIG. 8, for example, when a single dopant film is formed between the first and second layers EMA1 and EMA2, the energy transfer efficiency from the first host BH1 to the second host BH2 can be reduced and holes can be trapped in the dopant BD having a higher HOMO (Highest Occupied Molecular Orbital) energy level than the surrounding first and second hosts BH1 and BH2, which can cause a delay and reduction in hole transfer to the second layer EMA2. As such, Experimental Example 4 EX4 exhibits increased driving voltage and reduced efficiency and lifespan.

On the other hand, as in Experimental Example 2 EX2, the light emitting device according to the embodiment of the present disclosure is disposed such that the third layer EMA3 contacts the second common layer CML2 far from the interface of the first and second layers EMA1 and EMA2 where the recombination region is most intensified, thereby preventing the third layer EMA3 from affecting the recombination of the light emitting layer EML. The first and second layers EMA1 and EMA2 and the third layer EMA3 are disposed such that holes and electrons are supplied to the interface side of the first and second layers EMA1 and EMA2, whereby a significant increase in efficiency and lifespan is expected.

The light emitting device of FIG. 1 shows an example in which a light emitting layer EML having a configuration of a plurality of layers within the first and second electrodes AND and CAT has a single stack that emits the same color. The light emitting device according to the embodiment of the present disclosure is not limited to the structure of FIG. 1.

For example, even in a light emitting device including multiple stacks, the light emitting layer of at least one stack can be formed as a plurality of layers, as shown in FIG. 2, to obtain the effects of improving the lifespan and efficiency. Hereinafter, a light emitting device according to another embodiment of the present disclosure will be described.

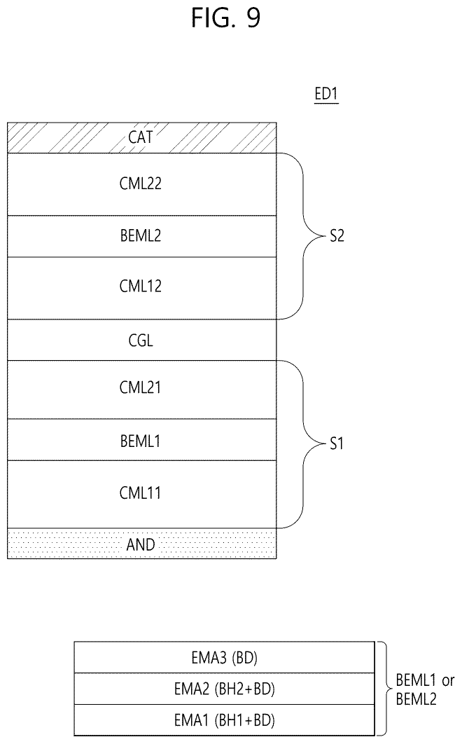

FIG. 9 is a cross-sectional view illustrating a light emitting device according to another embodiment of the present disclosure.

As shown in FIG. 9, the light emitting device ED1 according to another embodiment of the present disclosure has a structure in which a first stack S1, a charge generation layer CGL, and a second stack S2 are sequentially disposed between the first electrode AND and the second electrode CAT that face each other.

The first stack S1 and the second stack S2 each include a first common layer CML11 or CML12 functioning to transport holes, a blue light emitting layer BEML1 or BEML2, and a second common layer CML21 or CML22 functioning to transport electrons.

The first common layer CML11 or CML12 can include a hole injection layer, a hole transport layer, an electron blocking layer, and the like.

The second common layer CML21 or CML22 can include a hole blocking layer, an electron transport layer, an electron injection layer, and the like.

In a configuration having a plurality of stacks, the hole injection layer can contact the first electrode AND in the first stack S1 and the electron injection layer can contact the second electrode CAT in the second stack S2.

The charge generation layer CGL can include a stack of a p-type charge generation layer PCGL and an n-type charge generation layer NCGL.

Here, the first stack S1 includes a first blue light emitting layer BEML1 and the second stack S2 includes a second blue light emitting layer BEML2.

At least one of the first and second blue light emitting layers BEML1 and BEML2 can include first to third layers EMA1, EMA2, and EMA3 as described above with respect to FIGS. 1 and 2. The first to third layers EMA1, EMA2, and EMA3 commonly include a dopant BD. The first layer EMA1 includes a first host BH1, the second layer EMA2 includes a second host BH2 having a lower triplet energy level than the first host, and the third layer includes the dopant alone.

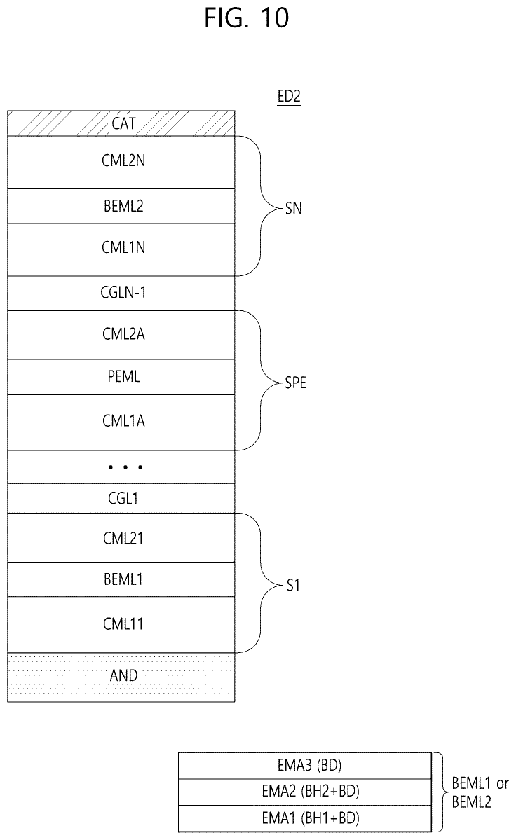

FIG. 10 is a cross-sectional view illustrating a light emitting device according to another embodiment of the present disclosure.

As shown in FIG. 10, the light emitting device ED2 according to this embodiment of the present disclosure includes three or more stacks between the first electrode AND and the second electrode CAT.

A charge generation layer CGL can be provided between three or more stacks S1, SPE, SN. The charge generation layer CGL can include a stack of an n-type charge generation layer NCGL and a p-type charge generation layer PCGL.

Two stacks S1 and SN among the three or more stacks provided between the first and second electrodes AND and CAT include blue light emitting layers BEML1 and BEML2.

The illustrated example shows a case in which the first stack S1 and the N^{th} stack SN include blue light emitting layers BEML1 and BEML2, but is not limited thereto.

One or more phosphorescent light emitting stacks SPE including a phosphorescent light emitting layer PEML can be provided between the first stack S1 and the N^{th} stack SN. In some cases, the phosphorescent light emitting layer PEML can be a stack of phosphorescent light emitting layers that emit different colors.

In each stack S1, SPE, SN, a hole transport first common layer CML11, CML1A, or CML1N can be provided at the bottom of each light emitting layer BEML1, PEML, or BEML2 and an electron transport first common layer CML21, CML2A or CML2N can be provided at the top of each light emitting layer BEML1, PEML, or BEML2.

For example, the first stack S1 includes a first blue light emitting layer BEML1 and the N^{th} stack S2 includes a second blue light emitting layer BEML2.

At least one of the first and second blue light emitting layers BEML1 and BEML2 can include first to third layers EMA1, EMA2, and EMA3 as described above with respect to FIGS. 1 and 2. The first to third layers EMA1, EMA2, and EMA3 commonly include a dopant BD. The first layer EMA1 includes a first host BH1, the second layer EMA2 includes a second host BH2 having a lower triplet energy level than the first host, and the third layer includes the dopant alone.

Hereinafter, an example in which the light emitting device described above is applied to a light emitting display device according to embodiments of the present disclosure will be described.

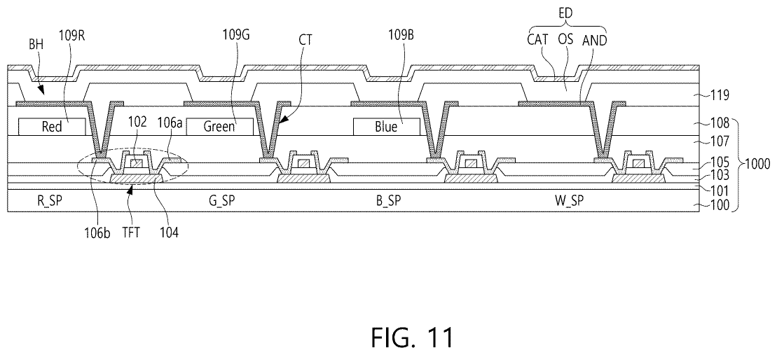

FIG. 11 is a cross-sectional view illustrating a light emitting display device including the light emitting device according to various embodiments of the present disclosure.

As shown in FIG. 11, the light emitting display device of the light emitting display device according to an embodiment of the present disclosure can emit light through a first electrode 110 on an emission side by applying the light emitting device described above to at least one of a plurality of subpixels R_SP, G_SP, B_SP, and W_SP. The light emitting display device includes a plurality of subpixels each including at least one light emitting device (e.g., ED) discussed herein according to various examples of the present disclosure. The light emitting display device can further include various other components associated with driving and operating the subpixels to display images.

The light emitting device ED of each subpixel can include a first electrode 110, a second electrode CAT, and an intermediate layer OS. The intermediate layer OS can include a plurality of stacks and have the same configuration in the plurality of subpixels R_SP, G_SP, B_SP, W_SP. In addition, the intermediate layer OS can include the electron transport stack between the plurality of stacks and the charge generation layer.

As shown in FIG. 11, the light emitting display device according to an embodiment of the present disclosure can include a substrate 100 having a plurality of subpixels R_SP, G_SP, B_SP, W_SP, a light emitting device ED commonly provided on the substrate 100, a thin film transistor TFT provided on each of the subpixels R_SP, G_SP, B_SP, W_SP and connected to the first electrode 110 of the light emitting device ED, and a color filter layer 109R, 109G, 109B provided under the first electrode 110 of at least one of the subpixels.

The example in FIG. 11 shows a case in which a white subpixel W_SP is included in the light emitting display device, but the present disclosure is not limited thereto, and a structure in which the white subpixel W_SP is omitted and only red, green, and blue subpixels R_SP, G_SP, B_SP are provided is also possible. In some cases, a combination of cyan subpixels, magenta subpixels, and yellow subpixels that express white by replacing red, green, and blue subpixels is also possible.

The thin film transistor TFT includes, for example, a gate electrode 102, a semiconductor layer 104, and a source electrode 106a and a drain electrode 106b connected to both sides of the semiconductor layer 104. In addition, a channel protection layer can be further provided on a portion where a channel of the semiconductor layer 104 is located to prevent direct connection between the source/drain electrodes 106a, 106b and the semiconductor layer 104. The thin film transistor TFT can include a buffer layer 101 on the substrate 100 and can be located on the buffer layer 101.

A gate insulating film 103 is provided between the gate electrode 102 and the semiconductor layer 104.

The semiconductor layer 104 can be formed of, for example, an oxide semiconductor, amorphous silicon, polycrystalline silicon, or a combination of two or more thereof. For example, when the semiconductor layer 104 is an oxide semiconductor, the heating temperature required to form a thin film transistor can be lowered, so that the substrate 100 can be used with a high degree of freedom, which is advantageous for application to a flexible display device.

A gate electrode 102 can be provided on the gate insulating film 103 and an interlayer insulating film 105 can be further provided between the gate electrode 102 and the source electrode 106a/drain electrode 106b.

In addition, the drain electrode 106b of the thin film transistor TFT can be connected to the first electrode 110 and the contact hole CT provided in the first and second protective films 107 and 108.

The first protective film 107 is provided primarily to protect the thin film transistor TFT, and a color filter 109R, 109G, 109B can be provided on the first protective film 107.

A second protective film 108 is provided on the first protective film 107 including the color filter 109R, 109G, 109B.

When the plurality of subpixels includes a red subpixel R_SP, a green subpixel G_SP, a blue subpixel B_SP, and a white subpixel W_SP, as shown in FIG. 11, the color filters are provided as first to third color filters 109R, 109G, 109B for the remaining subpixels R_SP, G_SP, B_SP except for the white subpixel W_SP, so as to allow white light emitted through the first electrode 110 to pass depending on each wavelength. In addition, a second protective film 108 is formed under the first electrode 110 to cover the first to third color filters 109R, 109G, 109B. The first electrode 110 is formed on the surface of the second protective film 108 excluding the contact hole CT and is connected to one of the drain electrode 106b and the source electrode 106a of the thin film transistor TFT to receive an electrical signal from the thin film transistor TFT.

Here, the thin film transistor array substrate 1000 can include the substrate 100, the thin film transistor TFT, the color filter 109R, 109G, 109B, and the first and second protective films 107 and 108.

The light emitting device ED is formed on a thin film transistor array substrate 1000 including a bank 119 defining a light emitting portion BH. The light emitting device ED can sequentially include a transparent first electrode 110, a second electrode 300 of a reflective electrode facing the first electrode 110, and a first common layer CML1 functioning to transport holes, a blue light emitting layer BEML including a first layer EMA1 including a first host BH1 and a blue dopant BD, a second layer EMA2 including a second host BH2 and a blue dopant BD, and a third layer EMA3 including a single blue dopant BD, and a second common layer CML2 functioning to transport electrons in at least one of the first and second blue stacks B1 and B2 among the stacks divided into the first and second charge generation layers CGL1 and CGL2 as described above between the first electrode 110 and the second electrode 300.

The first electrode 110 is divided into each subpixel, and the remaining layers excluding the first electrode 110 of the light emitting device ED can be provided as an integral part in the entire display area without distinction by subpixel.

Either the first electrode 110 or the second electrode 300 can be connected to the thin film transistor TFT.

The light emitting display device according to various examples of the present disclosure described above has a structure in which at least one light emitting layer in a stack includes the first to third layers EMA1, EMA2, and EMA3 described in FIGS. 1 and 2, thus exhibiting the effects of improved lifespan, improved efficiency, and reduced driving voltage.

Meanwhile, the light emitting display device of FIG. 11 described above is illustrated as a structure in which light is emitted downward, but the present disclosure is not limited thereto. For example, when the first electrode 110 includes a reflective electrode, the second electrode 300 is a transparent electrode or a reflective-transparent electrode, and the color filter is disposed above the second electrode 300, the light emitting display device can be applied in a top-emission manner.

In the structure described above, the intermediate layer OS of the light emitting device ED is common to each subpixel, but the light emitting display device of the embodiment of the present disclosure is not limited thereto.

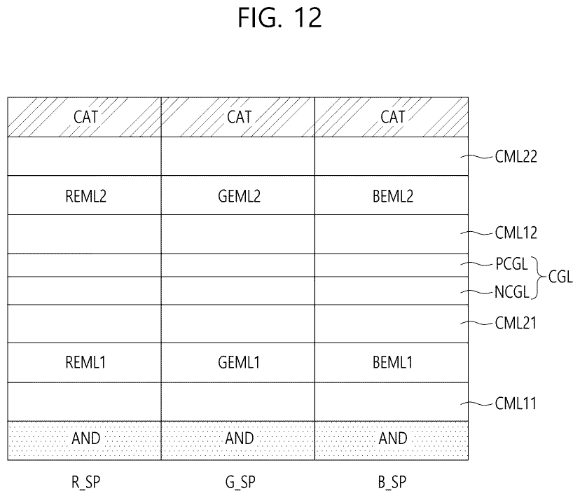

FIG. 12 is a cross-sectional view illustrating a light emitting display device according to another embodiment of the present disclosure.

As shown in FIG. 12, in addition, the light emitting display device according to this embodiment of the present disclosure can include a plurality of subpixels configured to display images. For example, the light emitting display device can include a first electrode 110 and a second electrode 300 facing each of a red subpixel R_SP, a green subpixel G_SP, and a blue subpixel B_SP, and a plurality of stacks between the first electrode 110 and the second electrode 300, wherein the plurality of stacks has overlapping light emitting layers that emit the same color. For example, the red subpixel R_SP can have red light emitting layers REML1 and REML2 in separate stacks with a charge generation layer CGL disposed therebetween, the green subpixel G_SP can have green light emitting layers GEML1 and GEML2 in separate stacks with the charge generation layer CGL disposed therebetween, and the blue subpixel B_SP can have blue light emitting layers BEML1 and BEML2 in separate stacks with the charge generation layer CGL disposed therebetween.

Here, a common layer CML11 related to hole injection and hole transport is provided between the first electrode 110 and the first red light emitting layer REML1, the first green light emitting layer GEML1, and the first blue light emitting layer BEML1, and a common layer CML21 related to electron transport is provided between each of the first red light emitting layer REML1, the first green light emitting layer GEML1, and the first blue light emitting layer BEML1, and the charge generation layer CGL.

The charge generation layer CGL can be provided by laminating an n-type charge generation layer nCGL and a p-type charge generation layer pCGL.

In addition, a common layer CML12 related to hole injection and hole transport can be provided between the charge generation layer CGL and the second red light emitting layer REML2, the second green light emitting layer GEML2, and the second blue light emitting layer BEML2, and a common layer CML22 including an electron transport layer and an electron injection layer can be provided between each of the second red light emitting layer REML2, the second green light emitting layer GEML2, and the second blue light emitting layer BEML2, and the second electrode 300.

The common layers CML11 and CML12 related to hole injection and transport can include at least one of a hole injection layer, a hole transport layer, and an electron blocking layer, and the common layers CML21 and CML22 related to electron transport and injection can include at least one of a hole blocking layer, an electron transport layer, and an electron injection layer.

Here, at least the first and second blue light emitting layers BEML1 and BEML2 provided in the blue subpixel B_SP have a structure including the first to third layers EMA1, EMA2, and EMA3 described in FIGS. 1 and 2, thus exhibiting the effects of improving lifespan, improving efficiency, and reducing driving voltage.

In the light emitting device and the light emitting display device including the same according to the embodiment of the present disclosure, first and second host supply sources and dopant supply sources with different properties are loaded in a single chamber, the first and second hosts are selectively supplied to the substrate to alternately form the first layer and the second layer including different hosts, and in the final stage, a shutter is loaded at a position where the host is supplied to provide the third layer provided with a single dopant at the top. For example, in the light emitting device and light emitting display device according to the embodiment of the present disclosure, the structure in which the light emitting layer in the light emitting device is divided into a plurality of hosts and formed into a plurality of light emitting layers is formed in a single chamber, thereby providing optimization of the process and solving the problem of reduced yield due to alignment errors occurring during movement within the chambers.

A light emitting device according to one embodiment of the present disclosure can comprise a first electrode and a second electrode facing each other and a first common layer, a first light emitting layer, and a second common layer sequentially disposed between the first electrode and the second electrode. The first light emitting layer can comprise a first layer, a second layer, and a third layer sequentially disposed between the first common layer and the second common layer, each comprising a dopant. The first layer can comprise a first host, the second layer can comprise a second host having a lower triplet energy level than the first host, and the third layer can comprise the dopant singly.

In the light emitting device according to one embodiment of the present disclosure, the third layer can contact the second common layer.

In the light emitting device according to one embodiment of the present disclosure, the dopant can be a fluorescent dopant having an emission peak at a wavelength of 430 nm to 495 nm.

In the light emitting device according to one embodiment of the present disclosure, a triplet energy level of the dopant can be higher than a triplet energy level of the first host.

In the light emitting device according to one embodiment of the present disclosure, a LUMO energy level of the dopant can be higher than a LUMO energy level of each of the first and second hosts.

In the light emitting device according to one embodiment of the present disclosure, a HOMO energy level of the dopant can be higher than a HOMO energy level of each of the first and second hosts.

In the light emitting device according to one embodiment of the present disclosure, the second common layer contacting the third layer can comprise an electron transport material.

In the light emitting device according to one embodiment of the present disclosure, a LUMO energy level of the electron transport material can be higher than a LUMO energy level of each of the first and second hosts and lower than a LUMO energy level of the dopant.

In the light emitting device according to one embodiment of the present disclosure, a thickness of the second layer can be greater than that of the first layer and a thickness of the third layer can be smaller than that of the first layer.

In the light emitting device according to one embodiment of the present disclosure, the thickness of the second layer can be at least twice that of the first layer, and the thickness of the third layer can be 1/200 to 1/10 times that of the first layer.

In the light emitting device according to one embodiment of the present disclosure, an intensity of light emitted from the first light emitting layer can be the highest at the interface between the first layer and the second layer.

In the light emitting device according to one embodiment of the present disclosure, the third layer can have a thickness of 0.1 Å to 5 Å.

The light emitting device according to one embodiment of the present disclosure can further comprise a charge generation layer, a third common layer, a second light emitting layer, and a fourth common layer sequentially disposed between the second common layer and the second electrode. The second light emitting layer can comprises the same structure as the first light emitting layer.

The light emitting device according to one embodiment of the present disclosure can further comprise a charge generation layer, a third common layer, a second light emitting layer, and a fourth common layer sequentially disposed between the second common layer and the second electrode. The second light emitting layer can emit light with a different color from the first light emitting layer.

In the light emitting device according to one embodiment of the present disclosure, a dopant of the first light emitting layer can be a blue light emitting dopant. The second light emitting layer can comprise a light emitting dopant having a longer wavelength than blue.

The light emitting device according to one embodiment of the present disclosure can further comprise at least one additional charge generation layer, an additional light emitting layer, and an additional common layer between the second common layer and the charge generation layer.

The light emitting display device according to one embodiment of the present disclosure can further comprise a substrate comprising a plurality of subpixels, a pixel circuit provided in each of the plurality of subpixels and the light emitting device connected to a thin film transistor of the pixel circuit.

A light emitting display device according to one embodiment of the present disclosure can comprise a substrate including a blue subpixel, a green subpixel, and a red subpixel, a pixel circuit at each of the blue subpixel, the green subpixel, and the red subpixel, a first electrode connected to a thin film transistor of the pixel circuit at each of the blue subpixel, the green subpixel, and the red subpixel, a second electrode facing the first electrode and a first common layer and a second common layer between the first electrode and the second electrode.

According to aspects of the present disclosure, the blue subpixel can comprise a first blue light emitting layer comprising a blue dopant between the first common layer and the second common layer.

According to aspects of the present disclosure, the green subpixel can comprise a first green light emitting layer comprising a green dopant between the first common layer and the second common layer.

According to aspects of the present disclosure, the red subpixel can comprise a first red light emitting layer comprising a red dopant between the first common layer and the second common layer.

According to aspects of the present disclosure, the first blue light emitting layer can comprise a first layer, a second layer, and a third layer sequentially disposed and each having the blue dopant. The first layer can comprise a first host, and the second layer can comprise a second host having a lower triplet energy level than the first host.

In the light emitting display device according to one embodiment of the present disclosure, a thickness of the second layer can be greater than that of the first layer, and a thickness of the third layer can be smaller than that of the first layer.

The light emitting display device according to one embodiment of the present disclosure can further comprise a charge generation layer, a third common layer, a color light emitting layer, and a fourth common layer between the second common layer and the second electrode. The color light emitting layer can comprise a second blue light emitting layer at the blue subpixel, a second green light emitting layer at the green subpixel, and a second red light emitting layer at the red subpixel.

According to aspects of the present disclosure, the second blue light emitting layer can have the same structure as the first blue light emitting layer.

The light emitting device and the light emitting display device including the same according to aspects of the present disclosure have the following effects and advantages.

Firstly, according to aspects of the present disclosure, first and second host supply sources and dopant supply sources having different properties are loaded in a single chamber, the first and second hosts are selectively supplied to the substrate to alternately form the first layer and the second layer including different hosts, and in the final stage, a shutter is loaded at a position where the host is supplied to provide the third layer provided with a single dopant at the top. For example, in the light emitting device and light emitting display device according to the embodiment of the present disclosure, the structure in which the light emitting layer in the light emitting device is divided into a plurality of hosts and formed into a plurality of light emitting layers is formed in a single chamber, thereby providing optimization of the process and solving the problem of reduced yield due to alignment errors occurring during movement within the chambers.

Secondly, according to aspects of the present disclosure, the first and second layers having hosts of different properties are capable of improving the luminous efficacy of pure color, reducing the driving voltage, and maximizing the lifespan.

Thirdly, according to aspects of the present disclosure, the third layer containing a single dopant in the light emitting layer has a difference in HOMO energy level from the adjacent layer, but is the uppermost thinnest layer of the light emitting layer, does not hinder the flow of electron transfer, is also separated from the recombination region in the light emitting layer, and does not reduce the luminous efficacy.

It will be apparent to those skilled in the art that various modifications and variations can be made in the present disclosure without departing from the spirit or scope of the inventions. Thus, it is intended that the present disclosure covers the modifications and variations of this invention provided they come within the scope of the appended claims and their equivalents.

What is claimed is:

1. A light emitting device comprising:
a first electrode and a second electrode facing each other; and
a first common layer, a first light emitting layer, and a second common layer disposed between the first electrode and the second electrode,
wherein the first light emitting layer comprises a first layer, a second layer, and a third layer that are sequentially disposed between the first common layer and the second common layer, each of the first layer, the second layer and the third layer comprising a dopant, and
wherein the first layer comprises a first host, the second layer comprises a second host having a lower triplet energy level than the first host, and the third layer comprises the dopant singly.

2. The light emitting device according to claim 1, wherein the third layer contacts the second common layer.

3. The light emitting device according to claim 1, wherein the dopant is a fluorescent dopant having an emission peak at a wavelength of 430 nm to 495 nm.

4. The light emitting device according to claim 1, wherein a triplet energy level of the dopant is higher than a triplet energy level of the first host.

5. The light emitting device according to claim 1, wherein a lowest unoccupied molecular orbital (LUMO) energy level of the dopant is higher than a LUMO energy level of each of the first and second hosts.

6. The light emitting device according to claim 1, wherein a highest occupied molecular orbital (HOMO) energy level of the dopant is higher than a HOMO energy level of each of the first and second hosts.

7. The light emitting device according to claim 1, wherein the second common layer contacting the third layer comprises an electron transport material.

8. The light emitting device according to claim 7, wherein a lowest unoccupied molecular orbital (LUMO) energy level of the electron transport material is higher than a LUMO energy level of each of the first and second hosts, and is lower than a LUMO energy level of the dopant.

9. The light emitting device according to claim 1, wherein a thickness of the second layer is greater than a thickness of the first layer, and
wherein a thickness of the third layer is smaller than the thickness of the first layer.

10. The light emitting device according to claim 1, wherein a thickness of the second layer is at least twice a thickness of the first layer, and
wherein a thickness of the third layer is 1/200 to 1/10 times the thickness of the first layer.

11. The light emitting device according to claim 9, wherein an intensity of light emitted from the first light emitting layer is highest at an interface between the first layer and the second layer.

12. The light emitting device according to claim 1, wherein the third layer has a thickness of 0.1 Å to 5 Å.

13. The light emitting device according to claim 1, further comprising a charge generation layer, a third common layer, a second light emitting layer, and a fourth common layer that are sequentially disposed between the second common layer and the second electrode,
wherein the second light emitting layer comprises a same structure as the first light emitting layer.

14. The light emitting device according to claim 1, further comprising a charge generation layer, a third common layer, a second light emitting layer, and a fourth common layer that are sequentially disposed between the second common layer and the second electrode,
wherein the second light emitting layer is configured to emit light with a different color from the first light emitting layer.

15. The light emitting device according to claim 14, wherein a dopant of the first light emitting layer is a blue light emitting dopant,
wherein the second light emitting layer comprises a light emitting dopant having a longer wavelength than blue.

16. The light emitting device according to claim 13, further comprising at least one additional charge generation layer, an additional light emitting layer, and an additional common layer between the second common layer and the charge generation layer.

17. A light emitting display device comprising:
a substrate comprising a plurality of subpixels;
a pixel circuit provided in each of the plurality of subpixels; and
the light emitting device according to claim 1, connected to a thin film transistor of the pixel circuit.

18. A light emitting display device comprising:
a substrate including a blue subpixel, a green subpixel, and a red subpixel;
a pixel circuit at each of the blue subpixel, the green subpixel, and the red subpixel;
a first electrode connected to a thin film transistor of the pixel circuit at each of the blue subpixel, the green subpixel, and the red subpixel;
a second electrode facing the first electrode; and
a first common layer and a second common layer between the first electrode and the second electrode,
wherein the blue subpixel comprises a first blue light emitting layer comprising a blue dopant between the first common layer and the second common layer,
wherein the green subpixel comprises a first green light emitting layer comprising a green dopant between the first common layer and the second common layer,
wherein the red subpixel comprises a first red light emitting layer comprising a red dopant between the first common layer and the second common layer,
wherein the first blue light emitting layer comprises a first layer, a second layer, and a third layer that are sequentially disposed, and each of the first layer, the second layer and the third layer includes the blue dopant, and
wherein the first layer of the first blue light emitting layer comprises a first host, and the second layer of the first blue light emitting layer comprises a second host having a lower triplet energy level than the first host.

19. The light emitting display device according to claim 18, wherein a thickness of the second layer of the first blue light emitting layer is greater than that of the first layer of the first blue light emitting layer, and
wherein a thickness of the third layer of the first blue light emitting layer is smaller than the thickness of the first layer of the first blue light emitting layer.

20. The light emitting display device according to claim 18, further comprising a charge generation layer, a third common layer, a color light emitting layer, and a fourth common layer between the second common layer and the second electrode,
wherein the color light emitting layer comprises a second blue light emitting layer at the blue subpixel, a second green light emitting layer at the green subpixel, and a second red light emitting layer at the red subpixel, and
wherein the second blue light emitting layer has a same structure as the first blue light emitting layer.
